(19) United States
(12) Patent Application Publication
(10) Pub. No.: US 2025/0385124 A1
(43) Pub. Date: Dec. 18, 2025

(54) SELF-ALIGNED GATE CUT STRUCTURE

(71) Applicant: International Business Machines Corporation, Armonk, NY (US)

(72) Inventors: Shay Reboh, Guilderland, NY (US); Junli Wang, Slingerlands, NY (US); Ruilong Xie, Niskayuna, NY (US); Indira Seshadri, Niskayuna, NY (US); Shahrukh Khan, Sandy Hook, CT (US); Muthumanickam Sankarapandian, Niskayuna, NY (US)

(21) Appl. No.: 18/742,604

(22) Filed: Jun. 13, 2024

(51) Int. Cl. H01L 21/762; H01L 27/088; H01L 29/06; H01L 29/423; H01L 29/775; H01L 29/786

(52) U.S. Cl. CPC H01L 21/76224; H10D 84/83; H10D 30/43; H10D 30/6735; H10D 30/6757; H10D 62/121

(57) ABSTRACT

A semiconductor device is provided that includes a self-aligned gate cut structure electrically isolating, at least in part, a gate structure of a first transistor from a gate structure of a second transistor. The distance from a semiconductor channel region of the first transistor to the self-aligned gate cut structure is the same as the distance from a semiconductor channel region of the second transistor to the self-aligned gate cut structure.

### BACKGROUND

The present application relates to semiconductor technology, and more particularly to a semiconductor device including a self-aligned gate cut structure.

As integrated circuits continue to scale downward in size, a number of challenges arise. For instance, reducing the size of memory and logic cells is becoming increasingly more difficult, as is reducing inter-device spacing at the device layer. A gate cut structure can be used to enable further scaling of semiconductor devices. A gate cut structure isolates gate structures of two adjacent transistors. Gate cut structures are typically formed by a gate cut process. Gate cut processes can include forming a gate cut trench into a sacrificial gate structure. The gate cut trench cuts the sacrificial gate structure into to discrete segments. Each gate cut trench is then filled with a dielectric material providing a gate cut structure. The discrete segments of the sacrificial gate structure are then replaced with a final gate structure in which the gate cut structure is located between each final gate structure.

### SUMMARY

A semiconductor device is provided that includes a self-aligned gate cut structure electrically isolating, at least in part, a gate structure of a first transistor from a gate structure of a second transistor. The distance from a semiconductor channel region of the first transistor to the self-aligned gate cut structure is the same as the distance from a semiconductor channel region of the second transistor to the self-aligned gate cut structure. In embodiments, the self-aligned gate cut structure lands on a shallow trench isolation such that the first transistor is entirely electrically isolated from the second transistor. In embodiments, one of the gate structures of the first transistor or second transistor extends between the self-aligned gate cut structure merging the first and second transistors together.

In one embodiment of the present application, the semiconductor device includes a first transistor including a first transistor semiconductor channel region and a first transistor gate structure contacting the first transistor semiconductor channel region, a second transistor is located adjacent to the first transistor and includes a second transistor semiconductor channel region and a second transistor gate structure contacting the second transistor semiconductor channel region, and a third transistor is located adjacent to the second transistor and includes a third transistor semiconductor channel region and a third transistor gate structure contacting the third transistor semiconductor channel region. The semiconductor device of this embodiment further includes a first gate cut structure located between the first transistor and the second transistor, and a second gate cut structure located between the second transistor and the third transistor. In the present application, a first distance from a first edge of the first gate cut structure to the first transistor semiconductor channel region is same as a second distance from a second edge of the first gate cut structure to the second transistor semiconductor channel region, and a third distance from a first edge of the second gate cut structure to the second transistor semiconductor channel region is same as a fourth distance from a second edge of the second gate cut structure to the third transistor semiconductor channel region, and the first distance, the second distance, the third distance and the fourth distance are equal to each other.

In another embodiment of the present application, the semiconductor device includes a first transistor including a first transistor semiconductor channel region and a first transistor gate structure contacting the first transistor semiconductor channel region, a second transistor is located adjacent to the first transistor and includes a second transistor semiconductor channel region and a second transistor gate structure contacting the second transistor semiconductor channel region, and a third transistor is located adjacent to the second transistor and includes a third transistor semiconductor channel region and a third transistor gate structure contacting the third transistor semiconductor channel region. The semiconductor device of this embodiment further includes a first gate cut structure located between the first transistor and the second transistor, and a second gate cut structure located between the second transistor and the third transistor. In the present application, a first distance from a first edge of the first gate cut structure to the first transistor semiconductor channel region is same as a second distance from a second edge of the first gate cut structure to the second transistor semiconductor channel region, and a third distance from a first edge of the second gate cut structure to the second transistor semiconductor channel region is same as a fourth distance from a second edge of the second gate cut structure to the third transistor semiconductor channel region, and the first distance, the second distance, the third distance and the fourth distance are equal to each other. In this embodiment, the first transistor gate structure extends beneath the first gate cut structure and contacts the second transistor gate structure, and the second gate cut structure lands on a shallow trench isolation structure that is located in a semiconductor device layer that is located beneath each of the first transistor, the second transistor and the third transistor.

In yet a further embodiment of the present application, the semiconductor device includes a first FET stack including a fourth transistor stacked above a first transistor, a second FET stack located adjacent to the first FET stack and including a fifth transistor stacked above a second transistor, and a third FET stack located adjacent to the second FET stack and including a sixth transistor stacked above a third transistor. In this embodiment, each of the first transistor, the second transistor and the third transistor includes a first semiconductor channel region of a first channel length and each of the fourth transistor, the fifth transistor and the sixth transistor includes a second semiconductor channel region of a second channel length that is less than the first channel length. The semiconductor device of this embodiment further includes a first gate cut structure located between the first transistor and the second transistor, a second gate cut structure located between the second transistor and the third transistor, a third gate cut structure located between the fourth transistor and the fifth transistor and in contact with the first gate cut structure, and a fourth gate cut structure located between the fifth transistor and the sixth transistor and in contact with the second gate cut structure. In this embodiment, the first gate cut structure and the third gate cut structure have a substantially same width, and the fourth gate cut structure has a width that is greater than a width of the second gate cut structure.

### BRIEF DESCRIPTION OF THE DRAWINGS

FIG. 1 is a cross sectional view of an exemplary semiconductor device in accordance with the present application.

FIG. 2 is a cross sectional view of another exemplary semiconductor device in accordance with the present application.

FIG. 3 is a cross sectional view of yet another exemplary semiconductor device in accordance with the present application.

FIG. 4 is a cross sectional view of a further exemplary semiconductor device in accordance with the present application.

FIG. 5 is a cross sectional view of a yet further exemplary semiconductor device in accordance with the present application.

FIGS. 6A-6H shows basic processing steps that can be used in forming self-aligned gate cut structures in accordance with the present application.

### DETAILED DESCRIPTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

The terms substantially, substantially similar, about, or any other term denoting functionally equivalent similarities refer to instances in which the difference in length, height, or orientation convey no practical difference between the definite recitation (e.g., the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

A transistor (or field effect transistor (FET)) includes a source region, a drain region, a semiconductor channel region located between the source region and the drain region, and a gate structure located above the semiconductor channel region. Collectively, the source region and the drain region can be referred to as a source/drain region. In the embodiment described in the present application, the transistor is a nanosheet transistor. A nanosheet transistor is a non-planar transistor that includes a vertical stack of spaced apart semiconductor channel material nanosheets as the semiconductor channel region with a pair of source/drain regions located at each of the ends of the vertical stack of spaced apart semiconductor channel material nanosheets. The gate structure includes a gate dielectric and a gate electrode. The gate structure wraps around each of the spaced apart semiconductor channel material nanosheets. Nanosheet transistors provide considerable scaling with high drive current capability. Nanosheet transistors provide a larger drive current for a given footprint compared to finFET technology. Although nanosheet transistors are described in this application, this application is not limited to nanosheet transistors. Instead, the present application can be used for finFETs and stack FETs (including stacked nanosheet transistors or stacked finFETs).

In the present application, the semiconductor device includes a frontside and a backside. The frontside includes a side of the device that includes at least one transistor, frontside contact structures, and a frontside back-end-of-the-line (BEOL) structure. The backside of the semiconductor device is the side of the device that is opposite the frontside. The backside includes backside contact structures, and a backside interconnect structure. The backside interconnect structure can be a backside power distribution network that is capable of delivering power to the transistor through the backside of the semiconductor device.

With respect to nanosheet transistors, the control of the distance between the gate cut structure and the semiconductor channel material nanosheets of each nanosheet transistor allows to increase the nanosheet width (for performance gains) or scale the cell size. For nanosheet-containing transistors a theoretical limit arrives when d is less than, or equal to, dsus, in which d is the distance from the end of the nanosheet and dsus in the distance between a stacked pair of nanosheets. To control d to dsus (which is about 10 nm) is extremely challenging. In the present application, a gate cut which is self-aligned to the active area and which can be scaled to less than 10 nm is disclosed. In the present application, the width of the gate cut structure is not lithography dependent and can be scaled by design to virtually any length. The present application provides independent control of the width of the gate cut structure and gate extension. In the present application, the gate cut structure is defined by a thickness of a first amorphous-Si layer used in forming a sacrificial gate structure, and the topography of the active area (therefore the first amorphous-Si layer is conformal). In one embodiment, the sacrificial gate structure includes a stack of, from bottom to top, a first intrinsic amorphous Si layer, a doped amorphous Si etch stop layer, and a second intrinsic amorphous Si layer. The etch stop layer allows, during sacrificial gate pull, to replace portions of the sacrificial gate structure with a self-aligned gate cut structure. By “self-aligned”, it is meant that a first distance from a first edge of the gate cut structure to the semiconductor channel region of a first transistor is same as a second distance from a second edge of the gate cut structure (which is opposite the first edge) to the semiconductor channel region of a second transistor that is located adjacent to the first transistor.

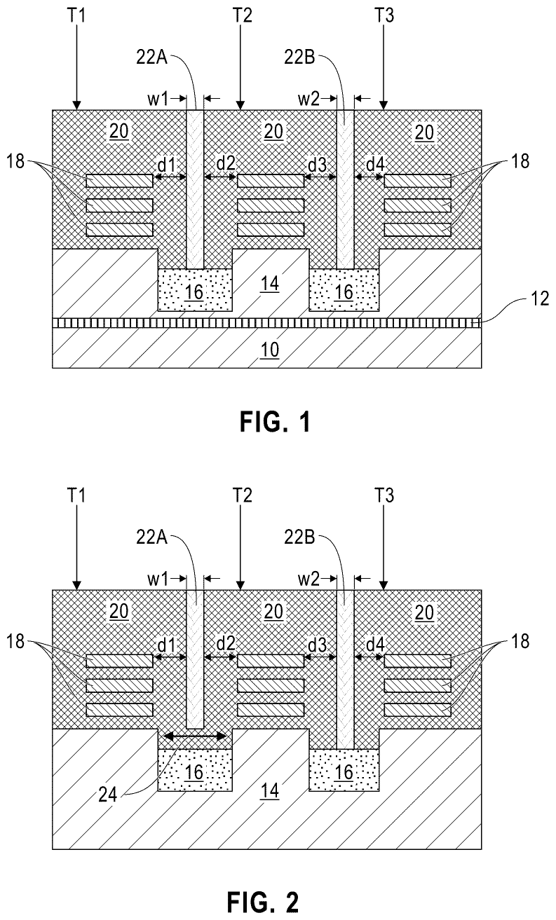

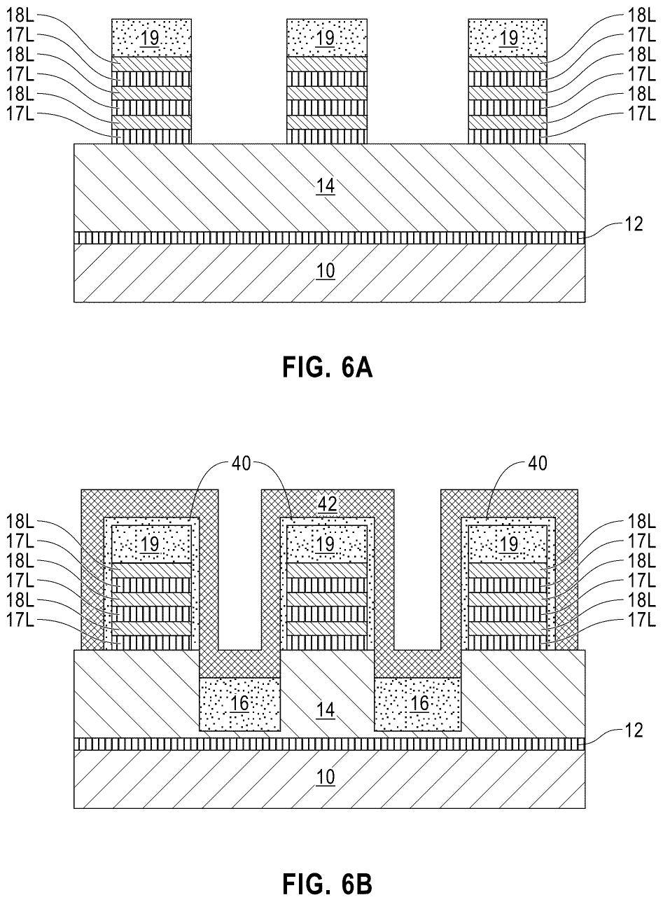

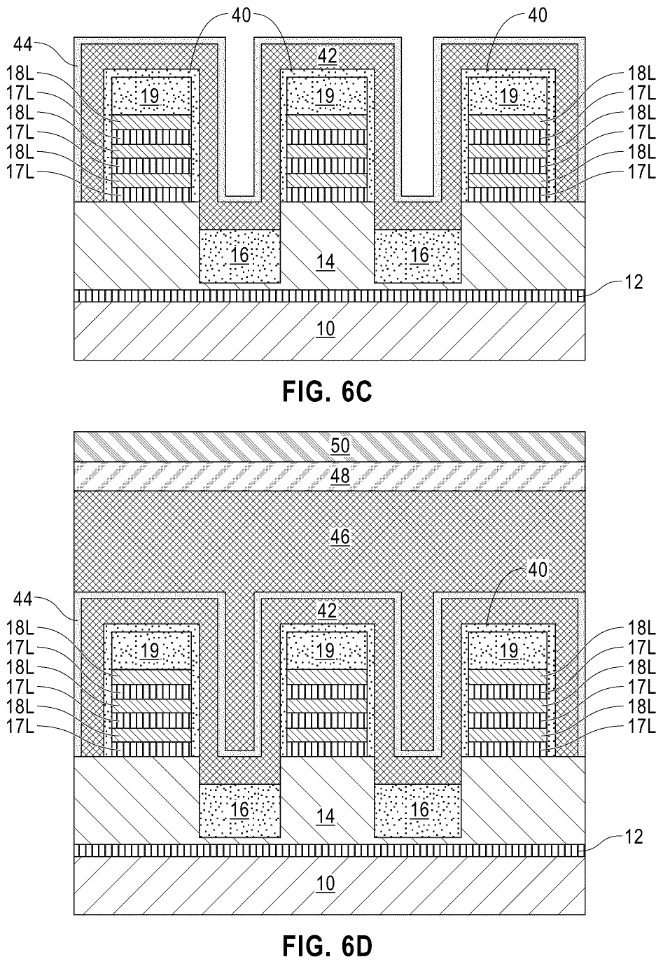

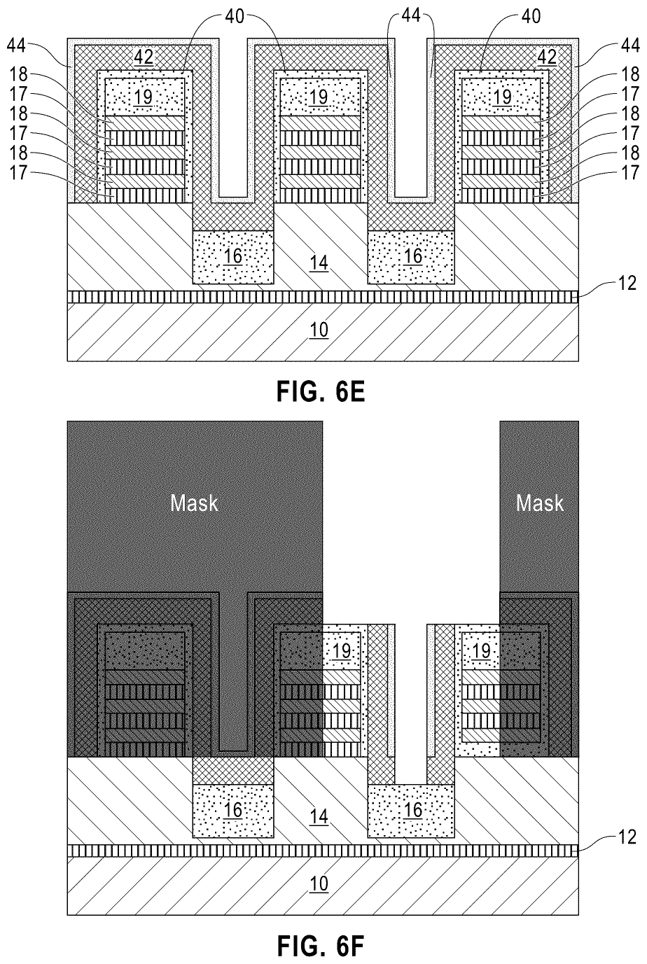

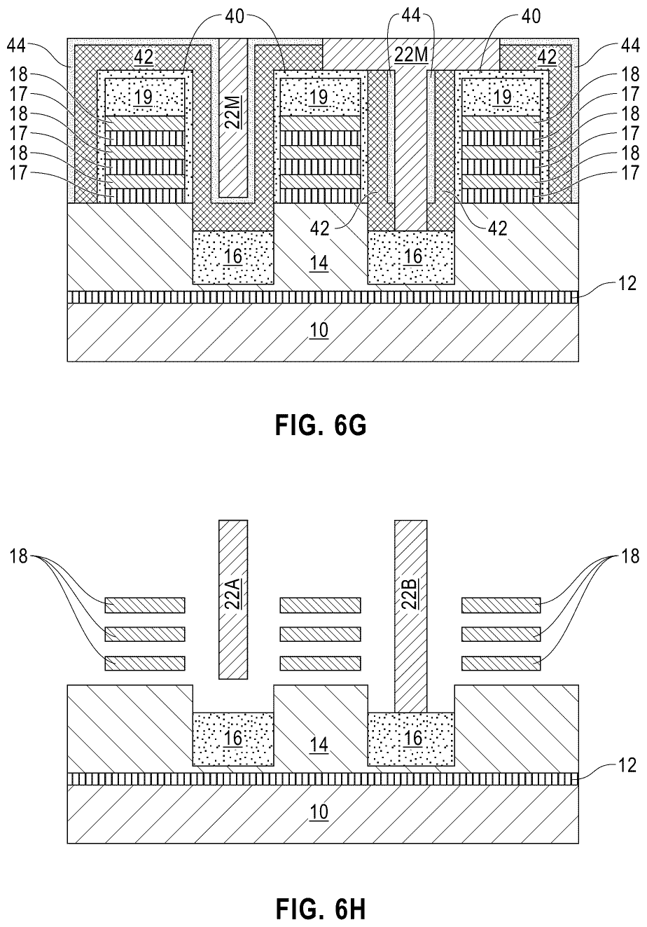

In the present application, the length of the gate cut structure and gate extension is defined by the thickness selected for the first intrinsic amorphous silicon (Si) layer and/or the doped amorphous Si etch stop layer, therefore, both can be engineered to any desired value including sub-10 nm with nm control and no “taper” effect. These are other aspects of the present application will be become more apparent in reference to the exemplary semiconductor devices shown in FIGS. 1-5 and the processing flow that is depicted in FIGS. 6A-H. It is noted that while amorphous Si is described as being used for each of the three layers of the sacrificial gate structure, amorphous Si can be replaced in any of, or all of, the layers with other amorphous semiconductor materials. Examples of other semiconductor materials beside Si that can be used include, but are not limited to, a silicon germanium (SiGe) alloy, a silicon germanium carbide (SiGeC) alloy, germanium (Ge), III/V compound semiconductors or II/VI compound semiconductors.

Referring first to FIG. 1, there is illustrated an exemplary semiconductor device in accordance with the present application. The exemplary semiconductor device of FIG. 1 includes a substrate that can include a semiconductor base layer 10, an etch stop layer 12, and a semiconductor device layer 14. Embodiments are contemplated in which the semiconductor base layer 10 and/or the etch stop layer 12 are omitted and the substrate includes only the semiconductor device layer 14. The semiconductor base layer 10 is composed of a first semiconductor material, and the semiconductor device layer 14 is composed of a second semiconductor material. It is noted that the term “semiconductor material” denotes a material that has semiconducting properties. Semiconductor materials include, but are not limited to, Si, a SiGe alloy, a SiGeC alloy, Ge, III/V compound semiconductors or II/VI compound semiconductors. The second semiconductor material that provides the semiconductor device layer 14 can be compositionally the same as, or compositionally different from, the first semiconductor material that provides the semiconductor base layer 10. In some embodiments of the present application, the etch stop layer 12 can be composed of a dielectric material such as, for example, silicon dioxide and/or boron nitride. In other embodiments of the present application, the etch stop layer 12 is composed of a third semiconductor material that is compositionally different from the first semiconductor material that provides the semiconductor base layer 10 and the second semiconductor material that provides the semiconductor device layer 14. In one example, the semiconductor base layer 10 is composed of silicon, the etch stop layer 12 is composed of silicon dioxide, and the semiconductor device layer 14 is composed of silicon. In another example, the semiconductor base layer 10 is composed of silicon, the etch stop layer 12 is composed of silicon germanium, and the semiconductor device layer 14 is composed of silicon.

Within the substrate, shallow trench isolation structures 16 are typically present. In the illustrated embodiment, the shallow trench isolation structures 16 are present in the semiconductor device layer 14 of the substrate. Each shallow trench isolation structure 16 is located between different active areas which contain different transistors. Each shallow trench isolation structure 16 can include a trench dielectric liner and a trench dielectric material. In some embodiments, the trench dielectric liner can be omitted. In one example, the trench dielectric liner is composed of SiN, and the trench dielectric material is composed of silicon dioxide. When present, the trench dielectric liner is present along a sidewall and a bottom wall of the trench dielectric material. In some embodiments, each shallow trench isolation structure 16 can have a topmost surface that is substantially coplanar with a topmost surface of the substrate (e.g., the semiconductor device layer 14). In other embodiments, each shallow trench isolation structure 16 can have a topmost surface that is vertically offset (i.e., higher or lower) than a topmost surface of the substrate (e.g., the semiconductor device layer 14).

The exemplary semiconductor device of FIG. 1 also includes three transistors (e.g., nanosheet transistors), namely T1, T2 and T3. As mentioned herein the nanosheet transistors can be replaced with finFETs. The number of transistors is not limited to three. Each transistor includes at least one vertical stack of spaced apart semiconductor channel material nanosheets 18 as a semiconductor channel region. In the present application, the semiconductor channel material nanosheets 18 of T1 can be referred to as first transistor semiconductor channel material nanosheets (or a first transistor semiconductor channel region), the semiconductor channel material nanosheets 18 of T2 can be referred to as second transistor semiconductor channel material nanosheets (or a second transistor semiconductor channel region), and the semiconductor channel material nanosheets 18 of T3 can be referred to as third transistor semiconductor channel material nanosheets (or a third transistor semiconductor channel region). Each semiconductor channel material nanosheets 18 is composed of a fourth semiconductor material. In some embodiments, the fourth semiconductor material that provides each semiconductor channel material nanosheet 18 can provide high channel mobility for n-type FET devices (i.e., NFETs). In other embodiments, the fourth semiconductor material that provides each semiconductor channel material nanosheet 18 can provide high channel mobility for p-type FET devices (PFETs). The fourth semiconductor material that provides each semiconductor channel material nanosheet 18 can include one of the semiconductor materials mentioned above. In one example, the fourth semiconductor material that provides each semiconductor channel material nanosheet 18 is composed of silicon.

In this exemplary embodiment, each of the transistors, e.g., T1, T2 and T3, also includes a gate structure 20. In the present application, the gate structure 20 of T1 can be referred to as a first transistor gate structure, the gate structure 20 of T2 can be referred to as a second transistor gate structure, and the gate structure 20 of T3 can be referred to as a third transistor gate structure. The gate structure 20 includes a gate dielectric material and a gate electrode, both of which are not separately shown, but intended to be within the region defined by gate structure 20. As is known to those skilled in the art, a gate dielectric material directly contacts a physically exposed surface(s) of the semiconductor channel region (e.g., the semiconductor channel material nanosheets 18), and a gate electrode is formed on the gate dielectric material.

The gate dielectric material has a dielectric constant of 4.0 or greater. All dielectric constants mentioned herein are relative to a vacuum unless otherwise noted. Illustrative examples of gate dielectric materials include, but are not limited to, silicon dioxide, hafnium dioxide (HfO₂), hafnium silicon oxide (HfSiO), hafnium silicon oxynitride (HfSiO), lanthanum oxide (La₂O₃), lanthanum aluminum oxide (LaAlO₃), zirconium dioxide (ZrO₂), zirconium silicon oxide (ZrSiO₄), zirconium silicon oxynitride (ZrSiOₓN_{y}), tantalum oxide (TaOₓ), titanium oxide (TiO), barium strontium titanium oxide (BaO₆SrTi₂), barium titanium oxide (BaTiO₃), strontium titanium oxide (SrTiO₃), yttrium oxide (Yb₂O₃), aluminum oxide (Al₂O₃), lead scandium tantalum oxide (Pb(Sc,Ta)O₃), and/or lead zinc niobite (Pb(Zn,Nb)O). The gate dielectric material can further include dopants such as lanthanum (La), aluminum (Al) and/or magnesium (Mg). The gate electrode can include a work function metal (WFM) and optionally a conductive metal. The WFM can be used to set a threshold voltage of the transistor to a desired value. In some embodiments, the WFM can be selected to effectuate an n-type threshold voltage shift. “N-type threshold voltage shift” as used herein means a shift in the effective work-function of the work-function metal-containing material towards a conduction band of silicon in a silicon-containing material. In one embodiment, the work function of the n-type work function metal ranges from 4.1 eV to 4.3 eV. Examples of such materials that can effectuate an n-type threshold voltage shift include, but are not limited to, titanium aluminum, titanium aluminum carbide, tantalum nitride, titanium nitride, hafnium nitride, hafnium silicon, or combinations thereof. In other embodiments, the WFM can be selected to effectuate a p-type threshold voltage shift. In one embodiment, the work function of the p-type work function metal ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the effective work-function of the work-function metal-containing material towards a valence band of silicon in the silicon containing material. Examples of such materials that can effectuate a p-type threshold voltage shift include, but are not limited to, titanium nitride, and tantalum carbide, hafnium carbide, and combinations thereof. The optional conductive metal can include, but is not limited to aluminum (Al), tungsten (W), or cobalt (Co).

The exemplary semiconductor device of FIG. 1 also includes a gate cut structure that electrically isolates two adjacent transistors from each other, e.g., T1 from T2, or T2 from T3. from each other. The gate cut structure is composed of a dielectric material such as, for example, silicon dioxide, silicon nitride and/or silicon oxynitride. In the illustrated embodiment, a first gate cut structure 22A and a second gate cut structure 22B are shown. The first gate cut structure 22A electrically isolates T1 from T2, and the second gate cut structure 22B electrically isolates T2 from T3. Each of the first gate cut structure 22A and the second gate cut structure 22B lands on (and thus is in direct physical contact with) one of the shallow trench isolation structures 16 and has a topmost surface that is substantially coplanar with a topmost surface of the gate structure 20. Each of the first gate cut structure 22A and the second gate cut structure 22B is a self-aligned gate cut structure, as defined above. Notably, and in respect to the first gate cut structure 22A, a first distance, d1, from the first gate cut structure 22A to each of the semiconductor channel material nanosheets 18 present in T1 is equal to a second distance, d2, from the first gate cut structure 22A to each of the semiconductor channel material nanosheets 18 present in T2. With respect to the second gate cut structure 22B, a third distance, d3, from the second gate cut structure 22B to each of the semiconductor channel material nanosheets 18 present in T2 is equal to a fourth distance, d4, from the second gate cut structure 22B to each of the semiconductor channel material nanosheets 18 present in T3. Note that d1, d2, d3 and d4 are equal to each other.

The first gate cut structure 22A has a first width, w1, and the second gate cut structure 22B has a second width, w2. In embodiments of the present application, w1 can be equal to w2, or w1 can be different (i.e., less than or greater than) from w2. In this exemplary embodiment, each of the first gate cut structure 22A and the second gate cut structure 22B have a same vertical height.

In the exemplary embodiment illustrated in FIG. 1, each gate structure (three of which are shown by way of one example) are entirely electrically isolated from each other by the gate cut structures (i.e., the first gate cut structure 22A and the second gate cut structure 22B).

Referring now to FIG. 2, there is illustrated another exemplary semiconductor device in accordance with the present application. The exemplary semiconductor device illustrated in FIG. 2 includes all of the elements shown in FIG. 1 except that the substrate is shown as only including the semiconductor device layer 14. The substrate can also include the semiconductor base layer 10 and/or the etch stop layer 12, both as mentioned above. In this example, the first gate cut structure 22A does not land on one of the shallow trench isolation structures 16; the second gate cut structure 22B does land on one of the shallow trench isolation structures 16. In the exemplary semiconductor device illustrated in FIG. 2, a gate extension (or strap) 24 is present beneath the first gate cut structure 22A that connects (i.e., merges) the gate structure 20 of T1 to the gate structure 20 of T2.

Each of the first gate cut structure 22A and the second gate cut structure 22B is a self-aligned gate cut structure, as defined above. Notably, and in respect to the first gate cut structure 22A, a first distance, d1, from the first gate cut structure 22A to each of the semiconductor channel material nanosheets 18 present in T1 is equal to a second distance, d2, from the first gate cut structure 22A to each of the semiconductor channel material nanosheets 18 present in T2. With respect to the second gate cut structure 22B, a third distance, d3, from the second gate cut structure 22B to each of the semiconductor channel material nanosheets 18 present in T2 is equal to a fourth distance, d4, from the second gate cut structure 22B to each of the semiconductor channel material nanosheets 18 present in T3. Note that d1, d2, d3 and d4 are equal to each other.

In the exemplary embodiment illustrated in FIG. 2, the gate structure 20 of T1 and the gate structure 20 of T2 merge under the first gate cut structure 22A, while the gate structure 20 of T3 is electrically isolated (in an entirety) from the merged gate structures of T1 and T2; the merged gate structures of T1 and T2 include gate extension 24 under the first gate cut structure 22A.

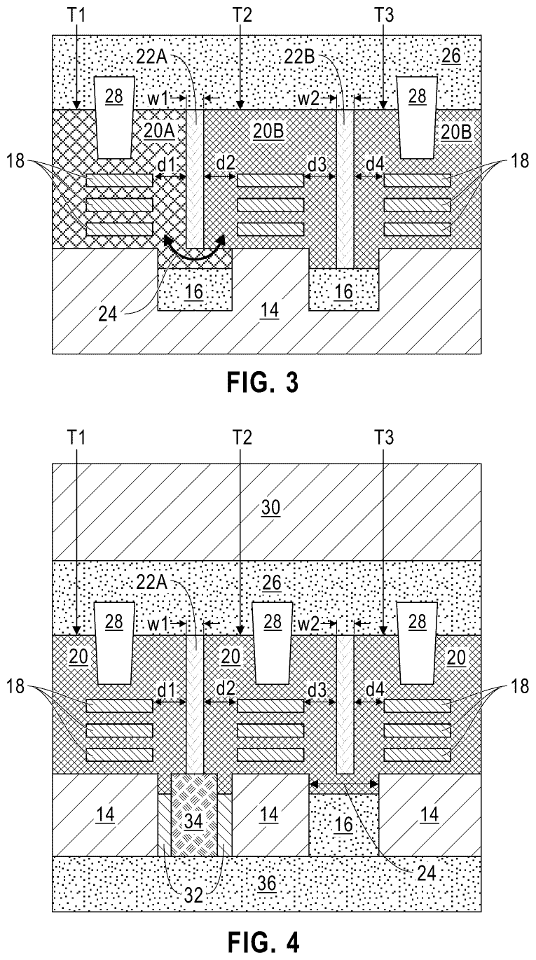

Referring now to FIG. 3, there is illustrated yet another exemplary semiconductor device in accordance with the present application. The exemplary semiconductor device illustrated in FIG. 3 includes all of the elements shown in FIG. 1 except that the substrate is shown as only including the semiconductor device layer 14. The substrate can also include the semiconductor base layer 10 and/or the etch stop layer 12, both as mentioned above. In this example, the first gate cut structure 22A does not land on one of the shallow trench isolation structures 16; the second gate cut structure 22B does land on one of the shallow trench isolation structures 16. In the exemplary semiconductor device illustrated in FIG. 3, gate extension (or strap) 24 is present beneath the first gate cut structure 22A that connects first gate structure 20A of T1 to the second gate structure 20B of T2. The second gate structure 20B of T3 is electrically isolated (in an entirety) from the second gate structure 20B of T2 by the second gate cut structure 20B. In this exemplary embodiment, the first gate structure 20A is compositionally different and/or of a different conductivity type than the second gate structure 20B. In this exemplary embodiment, the first gate structure 20A and the second gate structure 20B are composed of a gate dielectric material and a gate electrode as defined above for gate structure 20. In the illustrated exemplary embodiment, the gate extension 24 is composed of the first gate structure 20A; embodiments are possible in which the gate extension 24 is composed of the second gate structure 20B.

Each of the first gate cut structure 22A and the second gate cut structure 22B is a self-aligned gate cut structure, as defined above. Notably, and in respect to the first gate cut structure 22A, a first distance, d1, from the first gate cut structure 22A to each of the semiconductor channel material nanosheets 18 present in T1 is equal to a second distance, d2, from the first gate cut structure 22A to each of the semiconductor channel material nanosheets 18 present in T2. With respect to the second gate cut structure 22B, a third distance, d3, from the second gate cut structure 22B to each of the semiconductor channel material nanosheets 18 present in T2 is equal to a fourth distance, d4, from the second gate cut structure 22B to each of the semiconductor channel material nanosheets 18 present in T3. Note that d1, d2, d3 and d4 are equal to each other.

In the exemplary embodiment illustrated in FIG. 3, the first gate structure 20B of T1 extends under the first gate cut structure 22A and contacts the second gate structure 20B of T2 as shown in FIG. 3.

The exemplary embodiment illustrated in FIG. 3 also shows a middle-of-the-line (MOL) level/frontside BEOL structure (hereinafter combined frontside MOL/BEOL structure 26) which can include frontside gate contact structures 28. In the exemplary embodiment, one of illustrated frontside gate contact structures 28 provides electrical contact between the first gate structure 20A of T1 and the frontside BEOL structure of the combined frontside MOL/BEOL structure 26, and the other illustrated frontside gate contact structures 28 provides electrical contact between the second gate structure 20B of the T3 and the frontside BEOL structure of the combined frontside MOL/BEOL structure 26. Note that since the first gate structure 20A of T1 contacts the second gate structure 20B of T2, T2 would also be in electrical contacted with the frontside BEOL structure of the combined frontside MOL/BEOL structure 26. Embodiments are possible in which the frontside gate contact structure 28 is in contact with the second gate structure 20B of T2 instead of the first gate structure 20A of T1 as illustrated in FIG. 3.

The MOL level of the combined frontside MOL/BEOL structure 26 is composed of one or more interlayer dielectric (ILD) materials. Illustrative ILD materials that can be used in providing the frontside ILD region 28 include, but are not limited to, silicon oxide, silicon nitride, undoped silicate glass (USG), fluorosilicate glass (FSG), borophosphosilicate glass (BPSG), a spin-on low-k dielectric layer, a chemical vapor deposition (CVD) low-k dielectric layer or any combination thereof. The term “low-k” as used throughout the present application denotes a dielectric material that has a dielectric constant of less than 4.0.

The frontside gate contact structures 28 are present in the MOL level. Each frontside gate contact structure 28 is composed of at least a contact conductor material. The contact conductor material can include, for example, a silicide liner, such as Ni, Pt, NiPt, an adhesion metal liner, such as TiN, and conductive metals such as W, Cu, Al, Co, Ru, Mo, Os, Ir, Rh, or an alloy thereof. Each of the frontside gate contact structures 28 can also include one or more contact liners (not shown). In one or more embodiments, the contact liner (not shown) can include a diffusion barrier material. Exemplary diffusion barrier materials include, but are not limited to, Ti, Ta, Ni, Co, Pt, W, Ru, TiN, TaN, WN, WC, an alloy thereof, or a stack thereof such as Ti/TiN and Ti/WC. In one or more embodiments in which a contact liner is present, the contact liner (not shown) can include a silicide liner, such as Ti, Ni, NiPt, etc., and a diffusion barrier material, as defined above.

The frontside BEOL structure of the combined frontside MOL/BEOL structure 26 is composed of one or more interconnect dielectric layers that have frontside interconnect wiring embedded therein. The one or more interconnect dielectric layers can be composed of a ILD material as mentioned previously herein. The frontside interconnect wiring which can be in the form of a metal via, a metal line, a combined metal line/metal via or any combination thereof is composed of an electrically conductive metal or an electrically conductive metal alloy. Illustrative examples of electrically conductive metals that can be used include, but are not limited to, Cu, Al, Co, Ru, Mo, Os, Ir, or Rh. An illustrative electrically conductive alloy that can be used includes, but is not limited to, a Cu—Al alloy.

Although not illustrated in FIGS. 1 and 2, the exemplary semiconductor devices illustrated in FIGS. 1 and 2 can be modified to include the combined frontside MOL/BEOL structure 26 and frontside gate contact structures 28 shown in FIG. 3.

Referring now to FIG. 4, there is illustrated a further exemplary semiconductor device in accordance with the present application. The exemplary semiconductor device illustrated in FIG. 4 includes all of the elements shown in FIG. 1 except that the substrate is shown as only including the semiconductor device layer 14. The substrate can also include the semiconductor base layer 10 and/or the etch stop layer 12, both as mentioned above. In this example, nether the first gate cut structure 22A, nor the second gate cut structure 26B lands on one of the shallow trench isolation structures 16. In this exemplary embodiment, the first gate cut structure 22A, lands on a backside gate cut structure 34, while the gate structure 20 of T2 and gate structure 20 of T3 merge under the second gate cut structure 26B. Note that the gate structure 20 of T2 could be modified to be a first gate structure 20A, and the gate structure 20 of T3 could be modified to be a second gate structure 20B, both as defined above in respect to the exemplary embodiment illustrated in FIG. 3 above. In the exemplary semiconductor device illustrated in FIG. 4, gate extension (or strap) 24 is present beneath the second gate cut structure 22B that connects the gate structure 20 of T2 to the gate structure 20 of T3. In the exemplary embodiment illustrated in FIG. 4, the backside gate cut structure 34 can have a lower portion that is surrounded by a backside dielectric spacer 32. The backside gate cut structure 34 is composed of dielectric material as mentioned above for the first gate cut structure 22A, and the second gate cut structure 22B. The backside dielectric spacer 32 is composed of a dielectric spacer material such as, for example, silicon dioxide, silicon nitride, SiBCN, SiOCN or SiOC.

Each of the first gate cut structure 22A and the second gate cut structure 22B is a self-aligned gate cut structure, as defined above. Notably, and in respect to the first gate cut structure 22A, a first distance, d1, from the first gate cut structure 22A to each of the semiconductor channel material nanosheets 18 present in T1 is equal to a second distance, d2, from the first gate cut structure 22A to each of the semiconductor channel material nanosheets 18 present in T2. With respect to the second gate cut structure 22B, a third distance, d3, from the second gate cut structure 22B to each of the semiconductor channel material nanosheets 18 present in T2 is equal to a fourth distance, d4, from the second gate cut structure 22B to each of the semiconductor channel material nanosheets 18 present in T3. Note that d1, d2, d3 and d4 are equal to each other.

In the exemplary embodiment illustrated in FIG. 4, the gate structures of T2 and T3 are merged under the second gate cut structure 22B, while the gate structure 20 of T1 is electrically isolated from the merged gate structures of T2 and T3; the merged gate structures of T2 and T3 include the gate extension 24 under the second gate cut structure 22B.

The exemplary semiconductor device illustrated in FIG. 4 also includes the combined frontside MOL/BEOL structure 26 and frontside gate contact structures 28, as previously described above with respect to the exemplary embodiment illustrated in FIG. 3, a carrier wafer 30 and a backside power distribution network 36. In the exemplary embodiment, the backside power distribution network 36 is located beneath the semiconductor device layer 14 and it contacts both the backside gate cut structure 34 and the backside dielectric spacer 32.

The carrier wafer 30 is positioned on the combined frontside MOL/BEOL structure 26 and it used during backside processing which forms the backside gate cut structure 34, the backside dielectric spacer 32 and the backside power distribution network 36. The carrier wafer 30 is composed of a semiconductor material such as, for example, Si.

The backside power distribution network 36 is composed of one or more interconnect dielectric layers that have backside interconnect wiring embedded therein. The one or more interconnect dielectric layers can be composed of a ILD material as mentioned previously herein. The backside interconnect wiring which can be in the form of a metal via, a metal line, a combined metal line/metal via or any combination thereof is composed of an electrically conductive metal or an electrically conductive metal alloy, both as defined above.

It should be noted that the exemplary semiconductor devices shown in FIGS. 1, 2 and 3 can also be modified to include at least the backside power distribution network 36 located on the backside of those exemplary semiconductor devices.

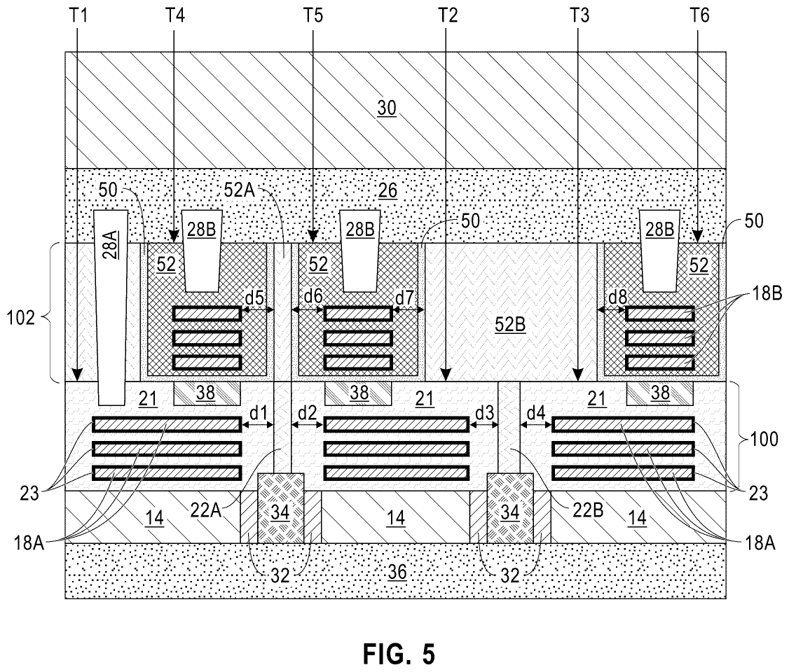

Referring now to FIG. 5, there is illustrated a yet further exemplary semiconductor device in accordance with the present application. The exemplary semiconductor device shown in FIG. 5 includes at least one transistor stacked on top of other transistor (i.e., a FET stack) in which the bottom transistor of each FET stack contains a first semiconductor channel region that has a first channel length and the top transistor of each FET stack contains a second semiconductor channel region that has a second channel length in which the second channel length is less than the first channel length. Notably, the exemplary semiconductor device illustrated in FIG. 5 includes a bottom transistor level 100 including three transistors, T1, T2 and T3 and a top transistor level 102 including three transistors, T4, T5 and T6 in which T1 and T4 form a first FET stack, T2 and T5 form a second FET stack and T3 and T6 form a third FET stack.

Each of the transistors is a nanosheet transistor including semiconductor channel material nanosheets and a gate structure (including a gate dielectric material and a bottom gate electrode as defined above). Notably, each nanosheet transistor in the bottom transistor level 100 includes first semiconductor channel material nanosheets 18A (of the first channel length) and a bottom gate structure that includes first gate dielectric material layer 23 and a first gate electrode 21. Each nanosheet transistor in the upper transistor level 102 includes second semiconductor channel material nanosheets 18B (having a second channel length less than the first channel length) and an upper gate structure that includes second gate dielectric material layer 50 and a second gate electrode 52. The first semiconductor channel material nanosheets 18A and the second semiconductor channel material nanosheets 18B are composed of a semiconductor material as defined above. The semiconductor material that provides the first semiconductor channel material nanosheets 18A can be compositionally the same as, or compositionally different from, the semiconductor material that provides the second semiconductor channel material nanosheets 18B. The first gate dielectric material layer 23 and the second gate dielectric material layer 50 include a gate dielectric material as mentioned above. The gate dielectric material that provides the first gate dielectric material layer 23 can be compositionally the same as, or compositionally different from, the gate dielectric material that provides the second gate dielectric material layer 50. The first gate electrode 21 and the second gate electrode 52 include a gate electrode material (i.e., WFM and optionally a conductive metal) as mentioned above. The gate electrode material that provides the first gate electrode 21 can be compositionally the same as, or compositionally different from, the gate electrode material that provides the second gate electrode 52. It is possible to have same conductivity type and/or different conductivity type transistors in each FET stack shown in FIG. 5. In this exemplary embodiment, the second gate structures have a width that is less than a width of each of the first gate structures and within each stack FET, an L-shaped or inverted L-shaped stacked FET is present.

In the exemplary semiconductor device of FIG. 5, within each FET stack the second gate dielectric material layer 50 can provide isolation between the second gate electrode 52 and the first gate electrode 21. In the exemplary embodiment, T1 is electrically isolated from T2 by first gate cut structure 22A, T2 is electrically isolated from T3 by second gate cute structure 22B, T4 is electrically isolated from T5 by third gate cut structure 52A and T5 is electrically isolated from T6 by a fourth gate cut structure 52B. The third gate cut structure 52A and the fourth gate structure 52B are composed of a dielectric material.

In the exemplary structure, the first FET stack is electrically isolated from the second FET stack by the combination of the first gate cut structure 22A and the third gate cut structure 52A (note that the third gate cut structure 52A is in contact with the first gate cut structure 22A), and the second FET stack is electrically isolated from the third FET stack by the combination of the second gate cut structure 22B and fourth gate cut structure 52B (note that the fourth gate cut structure 52B is in contact with the second gate cut structure 22B). In the present application, the fourth gate cut structure 52B has a width that is greater than a width of the second gate cut structure 22B thus the combination of the second gate cut structure 22B and fourth gate cut structure 52B provides a T-shaped gate cut structure, as is shown in FIG. 5. The first gate cut structure 22A and the third gate cut structure 52A can have a substantially same width.

Each of the first gate cut structure 22A and the second gate cut structure 22B is a self-aligned gate cut structure, as defined above. Notably, and in respect to the first gate cut structure 22A, a first distance, d1, from the first gate cut structure 22A to each of the first semiconductor channel material nanosheets 18A present in T1 is equal to a second distance, d2, from the first gate cut structure 22A to each of the first semiconductor channel material nanosheets 18A present in T2. With respect to the second gate cut structure 22B, a third distance, d3, from the second gate cut structure 22B to each of the first semiconductor channel material nanosheets 18A present in T2 is equal to a fourth distance, d4, from the second gate cut structure 22B to each of the first semiconductor channel material nanosheets 18A present in T3. Note that d1, d2, d3 and d4 are equal to each other.

Each of the third gate cut structure 52A and the fourth gate cut structure 52B is a self-aligned gate cut structure, as defined above Notably, and in respect to the third gate cut structure 52A, a fifth distance, d5, from the third gate cut structure 52A to each of the second semiconductor channel material nanosheets 18B present in T4 is equal to a sixth distance, d6, from the third gate cut structure 52A to each of the second semiconductor channel material nanosheets 18B present in T5. With respect to the fourth gate cut structure 52B, a seventh distance, d7, from the fourth gate cut structure 52B to each of the second semiconductor channel material nanosheets 18B present in T5 is equal to an eighth distance, d8, from the fourth gate cut structure 52B to each of the second semiconductor channel material nanosheets 18B present in T6. Note that d5, d6, d7 and d8 are to each other, and d5, d6, d7 and d8 are equal to d1, d2, d3 and d4.

In this exemplary embodiment, the first gate cut structure 22A and the second gate cut structure 22B can have a same height and a same width, and each lands on backside gate cut structure 34. The backside gate cut structure 34 can have a lower portion that is surrounded by backside dielectric spacer 32.

The exemplary semiconductor device shown in FIG. 5 also includes combined frontside MOL/BEOL structure 26, as defined above, which can include a frontside bottom gate contact structure 28A and frontside top gate contact structures 28B. The frontside bottom gate contact structure 28A and frontside top gate contact structures 28B are composed of least a contact conductor material as described above for frontside gate contact structures 28. The frontside bottom gate contact structure 28A contacts the first electrode 21 of T1; it is possible to form other frontside bottom gate contact structures that contact first electrode 21 of T2 and/or T3. Each frontside top gate contact structure 28B contacts second electrode 52 of T4, T5 or T6. In addition to including frontside bottom gate contact structure 28A and frontside top gate contact structures 28B, the exemplary semiconductor device illustrated in FIG. 5 further includes top/bottom frontside contact structures 38 that connect the T1 to T4, T2 to T5, and T3 to T6. Each top frontside gate contact structure and top/bottom frontside contact structure 38 is composed of least a contact conductor material as described above for frontside gate contact structures 28.

The exemplary semiconductor device shown in FIG. 5 also includes carrier wafer 30 (as defined above) located on top of the combined frontside MOL/BEOL structure 26, and a backside power distribution network 36 (as defined above) beneath the semiconductor device layer 14.

Referring now to FIGS. 6A-6H, there are illustrated basic processing steps that can be used in forming self-aligned gate cut structures in accordance with the present application. Notably, the basic processing steps illustrated in FIGS. 6A-6H provide the exemplary semiconductor device illustrated in FIG. 2. With a slight modification that is within the knowledge of a skilled artisan the processing steps illustrated in FIG. 6A-6H can be used in providing the exemplary semiconductor device illustrated in FIG. 1. With modification and addition of well-known frontside MOL/BEOL processing and/or well-known backside processing, the exemplary semiconductor devices illustrated in FIGS. 3 and 4 can be formed. By inserting the processing steps illustrated FIGS. 6A-6H (with modification of the masks) into a well-known stacked FET process, well-known frontside MOL/BEOL processing and well-known backside processing the exemplary semiconductor device shown in FIG. 5 can be formed.

Referring back to the basic processing steps illustrated in FIGS. 6A-6H, the process begins by providing the exemplary structure shown in FIG. 6A which includes patterned material stacks of alternating sacrificial semiconductor material layers 17L and semiconductor channel material layers 18L located on a surface of a substrate. Each material stack contains a sacrificial dielectric cap 19. The substrate can include semiconductor base layer 10, etch stop layer 12 and semiconductor device layer 14, each as defined above. The sacrificial semiconductor material layers 17L are composed of a semiconductor material such as, for example, SiGe, that is compositionally different from a semiconductor material (e.g., Si) that provides the semiconductor channel material layers 18L. The dielectric capped material stacks can be formed by deposition of alternating sacrificial semiconductor material layers 17L and semiconductor channel material layers 18L, followed by deposition of the dielectric material that provides the dielectric cap 19, followed by lithographic patterning. This steps defines active device areas for the transistors.

Throughout the present application, the terms “deposition” or “depositing” denotes one of chemical vapor deposition (CVD), plasma enhanced chemical vapor deposition (PECVD), physical vapor deposition (PVD), atomic layer deposition (ALD), epitaxial growth, spin-on coating, evaporation, plating or sputter. The appropriate selection of which type of deposition process to utilize is dependent on the material being deposited.

Throughout the present application, the term “lithographic patterning” denotes a patterning process in which photolithography and etching can be used to pattern a material layer or a stack of material layers. Photolithography includes depositing a photoresist material on a material layer or stack of material layers that need to be patterned, exposing the photoresist material to a desired pattern of irradiation and developing the exposed photoresist material to provide a patterned photoresist. Etching can include dry etching and/or wet etching. Dry etching can include, for example, reactive ion etching (RIE), ion beam etching (IBE), and plasma etching. Wet etching includes the use of an appropriate chemical etchant that has a high etch rate for one material as compared to at least one another material.

Next, and as is shown in FIG. 6B, shallow trench isolation structures 16 are formed into the semiconductor device layer 14 of the substrate utilizing techniques and materials (optional diffusion liner, e.g., SiN, and a trench dielectric material, e.g., SiO₂), that are well-known to those skilled in the art, thereafter forming a dielectric liner 40 (by a deposition process), followed by the formation a first intrinsic (i.e., non-doped) Si layer 42 by a conformal deposition process such as, for example, CVD or PECVD. The first intrinsic Si layer 42 follows the contour of the exemplary structure shown in FIG. 6A. The first intrinsic Si layer 42 is a conformal layer. The term “conformal layer” denotes a layer whose vertical height, as measured from a horizontal surface of a material layer or stack of material layers, is substantially the same as the thickness as measured from a vertical surface of the same material layer or stack of material layers. As mentioned above, silicon within the first intrinsic Si layer 42 can be replaced with other semiconductor materials as defined above.

Next, and as is shown in FIG. 6C, a doped amorphous Si layer 44 is formed on the first intrinsic Si layer 42 by a conformal deposition process. The doped amorphous Si layer 44 is thus a conformal layer as well. The dopant within the doped amorphous Si layer 44 includes well-known p-type dopants or n-type dopants. In one example, the dopant within the doped amorphous Si layer 44 is B. As mentioned above, Si within the doped amorphous Si layer 44 can be replaced with another semiconductor material.

Next, and as is shown in FIG. 6D, a second intrinsic Si layer 46 is formed on the doped amorphous Si layer 44 by a deposition process. A planarization process such as, for example, chemical mechanical polishing (CMP) can follow the deposition of the second intrinsic Si layer 46. In the present application, the first intrinsic Si layer 42, the doped amorphous Si layer 44, and the second intrinsic Si layer 46 are used as a sacrificial gate structure in which the doped amorphous Si layer 44 serves as an etch stop layer of the sacrificial gate structure.

Also, shown in FIG. 6D is the deposition of a first sacrificial gate cap layer 48 and a second sacrificial gate cap layer 50. The first sacrificial gate cap layer 48 is composed of a compositionally different hard mask material than the second sacrificial gate cap layer 50. For example, the first sacrificial gate cap layer 48 can be composed of silicon nitride, and the second sacrificial gate cap layer 50 can be composed of silicon dioxide.

At this point of the processing flow, a lithography patterning process (not specifically shown) can be used to pattern the material stack of the second sacrificial gate cap layer 50, the first sacrificial gate cap layer 48, the second intrinsic Si layer 46, the doped amorphous Si layer 44 and the first intrinsic Si layer 42 into a patterned sacrificial gate material-containing stack of the second sacrificial gate cap layer 50, the first sacrificial gate cap layer 48, the second intrinsic Si layer 46, the doped amorphous Si layer 44 and the first intrinsic Si layer 42. Next, gate spacers (not shown) are formed on the sidewalls of the patterned sacrificial gate material-containing stack and the gate spacers and the patterned sacrificial gate material-containing stack will serve as a combined etch mask during the nanosheet patterning of the material stack mentioned in FIG. 6A above. The gate spacers are composed of a gate spacer material and can be formed by deposition followed by a spacer etch. Following the formation of the gate spacers, each material stack is patterned to provide a nanosheet stack of alternating sacrificial semiconductor nanosheets 17 and semiconductor channel material nanosheets 18 (see, for example, FIG. 6E). Next, each sacrificial semiconductor material nanosheets 17 is recessed (the recessing is not shown in the cross sectional view of the drawings used in the present application), and thereafter inner spacers (not shown) and source/drain regions (not shown) are formed. The inner spacers are formed in the gap created by the recessing of the sacrificial semiconductor nanosheets 17 by deposition and etching. The source/drain regions are formed by a deposition process particularly an epitaxial growth process. The source/drain regions extend outward from exposed sidewalls of each of the semiconductor channel material nanosheets 18. The inner spacers are composed of a spacer dielectric material, and the source/drain regions are composed of a semiconductor material and a dopant.

After forming the source/drain regions, a frontside interlayer dielectric material layer (not shown) is formed by deposition and planarization. The planarization process typically removes the second sacrificial gate cap layer 50 from atop each patterned sacrificial gate material stack. See, FIG. 6E. After removing the second sacrificial gate cap layer 50, and as is further shown in FIG. 6E, the first sacrificial gate cap layer 48 is removed from top the patterned sacrificial gate material stack to reveal the second amorphous Si layer 46. The removal of the first sacrificial gate cap layer 48 includes any well-known material removal process that is selective in removing the first sacrificial gate cap layer 48. Next, and as is also shown in FIG. 6E, the second amorphous Si layer 46 is removed by an etching process that stops of the doped amorphous Si layer 44.

Referring now to FIG. 6F, there is illustrated the exemplary structure of FIG. 6E after forming a mask protecting a predetermined area of the structure, while leaving at least one other area as shown in FIG. 6F unprotected. The mask is composed of well-known masking material(s) and can be formed be depositing and photolithographic patterning. After mask formation, and as is also shown in FIG. 6F, the doped amorphous Si layer 44 and the first amorphous Si layer 42 are removed from all horizontal surfaces of the structure that are not protected by the mask. The removal of the doped amorphous Si layer 44 and the first amorphous Si layer 42 from all horizontal surfaces of the structure that are not protected by the mask can include one or more etching processes. The removal of the doped amorphous Si layer 44 and the first amorphous Si layer 42 from all horizontal surfaces of the structure that are not protected by the mask reveals the one of the shallow trench isolation structures 16 and adjacent sacrificial dielectric caps 19 of the structure.

Referring now to FIG. 6G, there is illustrated the exemplary structure of FIG. 6F after removing the mask and forming a dielectric material 22M. The mask can be removed utilizing any well-known material removal process. The dielectric material 22M is formed by deposition and planarization. FIG. 6G represents one embodiment in which the planarization stops on the uppermost portion of the doped amorphous Si layer 44. In another embodiment (not shown), the planarization process can stop on top of the sacrificial dielectric caps 19. The dielectric material 22M is used in forming the self-aligned gate cut structures of the present application.

Next, and as shown in FIG. 6H, there is illustrated the resultant structure after performing an initial step of a replacement gate process in which the remaining doped amorphous Si layer 44 and the remaining first amorphous Si layer 42 are removed, followed by the removal of the dielectric liner 40, the sacrificial dielectric caps 19 and each of the sacrificial semiconductor material nanosheets 17. A gate structure can then be formed (by deposition and planarization) to provide the exemplary semiconductor device illustrated in FIG. 2.

While the present application has been particularly shown and described with respect to preferred embodiments thereof, it will be understood by those skilled in the art that the foregoing and other changes in forms and details may be made without departing from the spirit and scope of the present application. It is therefore intended that the present application not be limited to the exact forms and details described and illustrated, but fall within the scope of the appended claims.

What is claimed is:

1. A semiconductor device comprising:
a first transistor comprising a first transistor semiconductor channel region and a first transistor gate structure contacting the first transistor semiconductor channel region;
a second transistor located adjacent to the first transistor and comprising a second transistor semiconductor channel region and a second transistor gate structure contacting the second transistor semiconductor channel region; and
a third transistor located adjacent to the second transistor and comprising a third transistor semiconductor channel region and a third transistor gate structure contacting the third transistor semiconductor channel region;
a first gate cut structure located between the first transistor and the second transistor; and
a second gate cut structure located between the second transistor and the third transistor, wherein a first distance from a first edge of the first gate cut structure to the first transistor semiconductor channel region is same as a second distance from a second edge of the first gate cut structure to the second transistor semiconductor channel region, and a third distance from a first edge of the second gate cut structure to the second transistor semiconductor channel region is same as a fourth distance from a second edge of the second gate cut structure to the third transistor semiconductor channel region, and wherein the first distance, the second distance, the third distance and the fourth distance are equal to each other.

2. The semiconductor device of claim 1, wherein the first gate cut structure and the second gate cut structure have a same vertical height and each of the first gate cut structure and the second gate cut structure lands on a shallow trench isolation structure that is located in a semiconductor device layer that is located beneath each of the first transistor, the second transistor and the third transistor.

3. The semiconductor device of claim 2, wherein the first gate cut structure and the second gate structure have different widths.

4. The semiconductor device of claim 1, wherein the first gate cut structure has a first vertical height and the second gate cut structure have a second vertical height, wherein the second vertical height differs from the first vertical height.

5. The semiconductor device of claim 4, wherein the first gate cut structure and the second gate structure have different widths.

6. The semiconductor device of claim 4, wherein the first vertical height of the first gate cut structure is less than the second vertical height of the second gate cut structure, and the first transistor gate structure and the second transistor gate structure merge under the first gate cut structure, and the second gate cut structure lands on a shallow trench isolation structure that is located in a semiconductor device layer that is located beneath each of the first transistor, second transistor and third transistor.

7. The semiconductor device of claim 6, wherein the first transistor gate structure and the second transistor gate structure are composed of a compositionally same gate dielectric material and gate electrode.

8. The semiconductor device of claim 1, wherein at least one of the first gate cut structure or the second gate cut structure lands on a surface of a backside gate cut structure, and the backside gate cut structure is in contact with a backside power distribution network.

9. The semiconductor device of claim 1, further comprising a combined frontside middle-of-the-line/back-end-of-the-line structure located above the first transistor, the second transistor, and the third transistor, and the combined frontside middle-of-the-line/back-end-of-the-line structure is electrically connected to each of the first transistor, the second transistor, and the third transistor via frontside gate contact structures.

10. The semiconductor device of claim 1, wherein each of the first transistor semiconductor channel region, the second transistor semiconductor channel region, and the third transistor semiconductor channel region is a vertical stack of spaced apart semiconductor channel material nanosheets.

11. A semiconductor device comprising:
a first transistor comprising a first transistor semiconductor channel region and a first transistor gate structure contacting the first transistor semiconductor channel region;
a second transistor located adjacent to the first transistor and comprising a second transistor semiconductor channel region and a second transistor gate structure contacting the second transistor semiconductor channel region; and
a third transistor located adjacent to the second transistor and comprising a third transistor semiconductor channel region and a third transistor gate structure contacting the third transistor semiconductor channel region;
a first gate cut structure located between the first transistor and the second transistor; and
a second gate cut structure located between the second transistor and the third transistor, wherein a first distance from a first edge of the first gate cut structure to the first transistor semiconductor channel region is same as a second distance from a second edge of the first gate cut structure to the second transistor semiconductor channel region, and a third distance from a first edge of the second gate cut structure to the second transistor semiconductor channel region is same as a fourth distance from a second edge of the second gate cut structure to the third transistor semiconductor channel region, and wherein the first distance, the second distance, the third distance and the fourth distance are equal to each other, and further wherein the first transistor gate structure extends beneath the first gate cut structure and contacts the second transistor gate structure, and the second gate cut structure lands on a shallow trench isolation structure that is located in a semiconductor device layer that is located beneath each of the first transistor, second transistor and third transistor.

12. The semiconductor device of claim 11, wherein the first transistor gate structure is compositionally different from the second transistor gate structure.

13. The semiconductor device of claim 11, wherein the first transistor gate structure is of a different conductivity type than the second transistor gate structure.

14. The semiconductor device of claim 11, further comprising a combined frontside middle-of-the-line/back-end-of-the-line structure located above the first transistor, the second transistor, and the third transistor, and the combined frontside middle-of-the-line/back-end-of-the-line structure is electrically connected to each of the first transistor, the second transistor, and the third transistor via frontside gate contact structures.

15. The semiconductor device of claim 11, wherein each of the first transistor semiconductor channel region, the second transistor semiconductor channel region, and the third transistor semiconductor channel region is a vertical stack of spaced apart semiconductor channel material nanosheets.

16. A semiconductor device comprising:
a first FET stack comprising a fourth transistor stacked above a first transistor;
a second FET stack located adjacent to the first FET stack and comprising a fifth transistor stacked above a second transistor;
a third FET stack located adjacent to the second FET stack and comprising a sixth transistor stacked above a third transistor, wherein each of the first transistor, the second transistor and the third transistor comprises a first semiconductor channel region of a first channel length and each of the fourth transistor, the fifth transistor and the sixth transistor comprises a second semiconductor channel region of a second channel length that is less than the first channel length;
a first gate cut structure located between the first transistor and the second transistor;
a second gate cut structure located between the second transistor and the third transistor; a third gate cut structure located between the fourth transistor and the fifth transistor and in contact with the first gate cut structure; and
a fourth gate cut structure located between the fifth transistor and the sixth transistor and in contact with the second gate cut structure, wherein the first gate cut structure and the third gate cut structure have a substantially same width, and the fourth gate cut structure has a width that is greater than a width of the second gate cut structure.

17. The semiconductor device of claim 16, wherein a first distance from the first gate cut structure to each of the first semiconductor channel region of the first transistor is equal to a second distance from the first gate cut structure to the second semiconductor channel region of the second transistor, and a third distance from the second gate cut structure to the first semiconductor channel region of the second transistor is equal to a fourth distance from the second gate cut structure to the first semiconductor channel region of the third transistor, and a fifth distance from the third gate cut structure to the second semiconductor channel region of the fourth transistor is equal to a sixth distance from the third gate cut structure to each of the second semiconductor channel regions of the fifth transistor, a seventh distance from the fourth gate cut structure to each of the second semiconductor channel region of the fifth transistor is equal to an eighth distance from the fourth gate cut structure to each of the second semiconductor channel region of the sixth transistor, and wherein the first distance, the second distance, the third distance, the fourth distance, the fifth distance, the sixth distance, the seventh distance and the eighth distance are equal to each other.

18. The semiconductor device of claim 16, wherein each of the first gate cut structure and the second gate cut structure lands on a backside gate cut structure that is present in a semiconductor device layer that is located beneath of the first FET stack, the second FET stack and the third FET stack.

19. The semiconductor device of claim 18, further comprising a backside power distribution network structure located beneath the semiconductor device layer and in contact with each of the backside gate cut structures.

20. The semiconductor device of claim 16, further comprising a combined frontside middle-of-the-line/back-end-of-the-line structure located above the first FET stack, the second FET stack and the third FET stack.
